(19) United States
(12) Patent Application Publication
(10) Pub. No.: US 2025/0260368 A1
(43) Pub. Date: Aug. 14, 2025

(54) COMPACT VOLTAGE COMBINED DOHERTY POWER AMPLIFIER

(71) Applicant: QUALCOMM Incorporated, San Diego, CA (US)

(72) Inventors: Pavel AFANASYEV, Helsinki (FL); Paolo Enrico DE FALCO, San Diego, CA (US); Sunbo SHIM, San Diego, CA (US); David Angel CALVILLO CORTES, San Diego, CA (US); Lei MA, Palo Alto, CA (US); Antonino SCUDERI, San Diego, CA (US)

(21) Appl. No.: 18/440,077

(22) Filed: Feb. 13, 2024

(51) Int. Cl. H03F 1/02; H03F 1/56; H03F 3/195; H03F 3/24

(52) U.S. Cl. CPC H03F 1/0288; H03F 1/565; H03F 3/195; H03F 3/245; H03F 2200/451

(57) ABSTRACT

A Doherty power amplifier (PA) includes a main amplifier, an auxiliary amplifier, and a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between the first RF signal and the second RF signal. The Doherty PA also includes a shunt inductor coupled to an output of the main amplifier, a shunt capacitor coupled to an output of the auxiliary amplifier, and a transformer. The transformer includes a first inductor coupled between the output of the main amplifier and the output of the auxiliary amplifier, and a second inductor magnetically coupled with the first inductor.

### BACKGROUND

### Field

Aspects of the present disclosure relate generally to wireless communications, and, more particularly, to power amplifiers.

### Background

A wireless device includes a transmitter for transmitting radio frequency (RF) signals via one or more antennas. The transmitter may include power amplifiers for amplifying the RF signals before transmission. One or more of the power amplifiers may be implemented with a Doherty power amplifier, which includes a main amplifier and an auxiliary amplifier.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a Doherty power amplifier (PA). The Doherty PA includes a main amplifier, an auxiliary amplifier, and a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between the first RF signal and the second RF signal. The Doherty PA also includes a shunt inductor coupled to an output of the main amplifier, a shunt capacitor coupled to an output of the auxiliary amplifier, and a transformer. The transformer includes a first inductor coupled between the output of the main amplifier and the output of the auxiliary amplifier, and a second inductor magnetically coupled with the first inductor.

A second aspect relates to a system for wireless communications. The system includes a radio frequency front-end (RFFE) module coupled to an antenna. The RFFE circuit includes a main amplifier, an auxiliary amplifier, and a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal. The RFFE module also includes a shunt inductor coupled to an output of the main amplifier, a shunt capacitor coupled to an output of the auxiliary amplifier, and a transformer. The transformer includes a first inductor coupled between the output of the main amplifier and the output of the auxiliary amplifier, and a second inductor magnetically coupled with the first inductor and coupled to the antenna.

A third aspect relates to a Doherty power amplifier (PA). The Doherty PA includes a main amplifier, an auxiliary amplifier, and a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal. The Doherty PA also includes a shunt inductor coupled to an output of the main amplifier, a shunt capacitor coupled to an output of the auxiliary amplifier, and a differential load coupled between the output of the main amplifier and the output of the auxiliary amplifier.

### BRIEF DESCRIPTION OF THE DRAWINGS

FIG. 1 shows an example of a current combined Doherty power amplifier according to certain aspects of the present disclosure.

FIG. 2 shows an example of a voltage combined Doherty power amplifier according to certain aspects of the present disclosure.

FIG. 3 shows an example of a Doherty power amplifier including a shunt inductor and a shunt capacitor according to certain aspects of the present disclosure.

FIG. 4A shows an exemplary mathematical model of a shunt device according to certain aspects of the present disclosure.

FIG. 4B shows an exemplary mathematical model of an output network of a Doherty power amplifier according to certain aspects of the present disclosure.

FIG. 5 shows an example of a Doherty power amplifier including a transformer providing voltage combining according to certain aspects of the present disclosure.

FIG. 6 shows another example of a Doherty power amplifier including a transformer providing voltage combining according to certain aspects of the present disclosure.

FIG. 7 shows an exemplary implementation of a power splitting and phase shifting circuit including a phase shifter according to certain aspects of the present disclosure.

FIG. 8 shows an exemplary implementation of the phase shifter of FIG. 7 according to certain aspects of the present disclosure.

FIG. 9 shows an exemplary implementation of a power splitting and phase shifting circuit including a first phase shifter and a second phase shifter according to certain aspects of the present disclosure.

FIG. 10 shows an exemplary implementation of a power splitting and phase shifting circuit including a power splitter according to certain aspects of the present disclosure.

FIG. 11 shows an exemplary implementation of a first phase shifter and a second phase shifter according to certain aspects of the present disclosure.

FIG. 12 shows an exemplary implementation of a main amplifier and an auxiliary amplifier according to certain aspects of the present disclosure.

FIG. 13 shows another exemplary implementation of a main amplifier and an auxiliary amplifier according to certain aspects of the present disclosure.

FIG. 14 shows yet another exemplary implementation of a main amplifier and an auxiliary amplifier according to certain aspects of the present disclosure.

FIG. 15 shows an example where a main amplifier and an auxiliary amplifier include multiple stages according to certain aspects of the present disclosure.

FIG. 16A shows an exemplary implementation of a main amplifier including multiple stages according to certain aspects of the present disclosure.

FIG. 16B shows an exemplary implementation of an auxiliary amplifier including multiple stages according to certain aspects of the present disclosure.

FIG. 17A shows an example of an RF front-end module according to certain aspects of the present disclosure.

FIG. 17B shows another example of an RF front-end module according to certain aspects of the present disclosure.

FIG. 18A shows an example of the RF front-end module of FIG. 17A including a shunt capacitor integrated on a die according to certain aspects of the present disclosure.

FIG. 18B shows an example of the RF front-end module of FIG. 17B including a shunt capacitor integrated on a die according to certain aspects of the present disclosure.

FIG. 19 shows an example of an RF front-end module of including capacitors coupled in parallel with inductors of a transformer according to certain aspects of the present disclosure.

FIG. 20 shows an exemplary implementation of a transformer according to certain aspects of the present disclosure.

FIG. 21 shows another exemplary implementation of a transformer according to certain aspects of the present disclosure.

FIG. 22 shows yet another exemplary implementation of a transformer according to certain aspects of the present disclosure.

FIG. 23 is a diagram of an environment including an electronic device that includes a transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

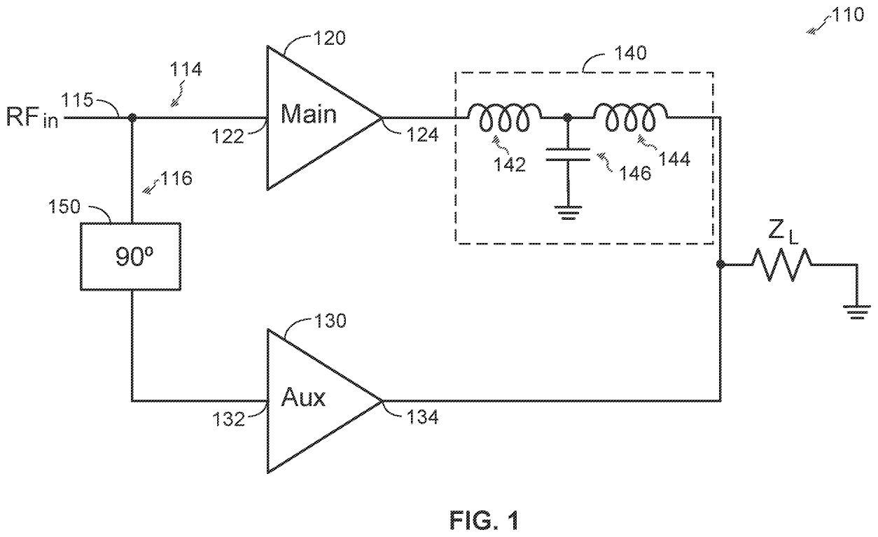

FIG. 1 shows an example of a Doherty power amplifier (PA) 110 according to certain aspects. The Doherty PA 110 may be used in a mobile device or a base station to provide efficient power amplification of a radio frequency (RF) signal having a high peak-to-average power ratio (PAPR). For example, a mobile device or a base station using high- order modulation schemes for high data throughput may generate an RF signal having a high PAPR.

In this example, the Doherty PA 110 receives an input RF signal (labeled “RF_{IN}”) at an input 115, amplifies the RF signal, and outputs the amplified RF signal to a load (labeled “Z_{L}”). The load may include an antenna, a transmission line, any combination thereof, etc. The input RF signal may come from a mixer (not shown) configured to frequency upconvert a baseband signal or an intermediate frequency (IF) signal into the input RF signal.

As shown in FIG. 1, the power of the input RF signal is split between a first path 114 and a second path 116 in the Doherty PA 110. The first path 114 includes a main amplifier 120 having an input 122 coupled to the input 115 of the Doherty PA 110. The main amplifier 120 may also be referred to as a carrier amplifier or another term. The second path 116 includes an auxiliary amplifier 130 and a 90-degree phase shifter 150, in which the 90-degree phase shifter 150 is coupled between the input 115 of the Doherty PA 110 and an input 132 of the auxiliary amplifier 130. The auxiliary amplifier 130 may also referred to as a peaking amplifier or another term.

The Doherty PA 110 also includes an impedance inverter 140. In this example, the impedance inverter 140 is coupled between an output 124 of the main amplifier 120 and the load Z_{L}, and an output 134 of the auxiliary amplifier 130 is coupled to the load Z_{L}. The impedance inverter 140 may be implemented with a Pi network, a T network, or a quarter-wavelength transmission line. In the example shown in FIG. 1, the impedance inverter 140 is implemented with a T network including a first inductor 142, a second inductor 144, and a shunt capacitor 146. The impedance inverter 140 introduces a 90-degree phase shift in the first path 114 (i.e., the main amplifier path). The 90-degree phase shifter 150 in the second path 116 (i.e., auxiliary amplifier path) compensates for the 90 degree phase shift of the impedance inverter 140.

The main amplifier 120 may be biased in class AB and may be always on (i.e., active) when the main amplifier 120 is provided with a supply voltage. The auxiliary amplifier 130 is biased in class C. In certain aspects, the auxiliary amplifier 130 may be configured to turn on when the main amplifier 120 is driven into saturation. In this example, the output RF signals from the main amplifier 120 and the auxiliary amplifier 130 are combined using current combining to drive the load Z_{L}.

In operation, when the power level of the input RF signal is low, the auxiliary amplifier 130 is turned off and the main amplifier 120 provides amplification of the input RF signal. As used herein, the power level of the input RF signal is low when the main amplifier 120 is driven below saturation. When the power level of the input RF signal is high enough to drive the main amplifier 120 into saturation or within some range of saturation, the auxiliary amplifier 130 turns on and provides additional amplification of the input RF signal. Thus, when the main amplifier 120 is driven into or close to saturation, both the main amplifier 120 and the auxiliary amplifier 130 contribute to amplification of the input RF signal. The output RF signal of the auxiliary amplifier 130 modulates the impedance at the output 124 of the main amplifier 120 to maintain high power efficiency when the main amplifier 120 operates in the saturation region. In this example, the power efficiency of the Doherty PA 110 as a function of input power may have a first efficiency peak corresponding to a back-off power and a second efficiency peak corresponding to a peak power of the Doherty PA 110. The back-off power may be the power at which the main amplifier 120 enters saturation. In certain aspects, the back-off power may be approximately 6 dB below the peak power.

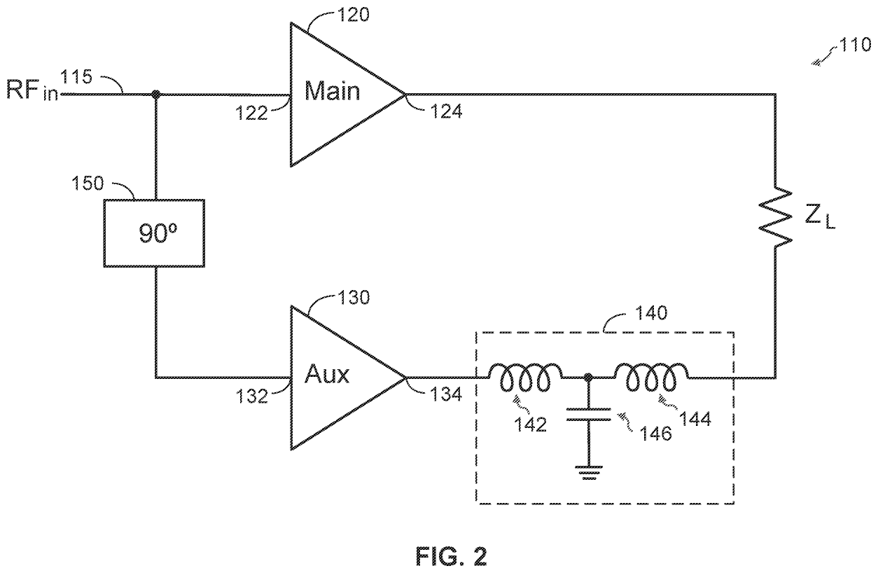

FIG. 1 shows an example in which the output RF signals of the main amplifier 120 and the auxiliary amplifier 130 are combined using current combining to drive a shunt load Z_{L}. FIG. 2 shows another example in which the output RF signals of the main amplifier 120 and the auxiliary amplifier 130 are combined using voltage combining (also referred to as voltage-mode combining) to drive a series load Z_{L}. In this example, the impedance inverter 140 is coupled between the output 134 of the auxiliary amplifier 130 and the load Z_{L}, and the output 124 of the main amplifier 120 is coupled to the load Z_{L}.

As shown in FIGS. 1 and 2, the output network of the Doherty PA 110 includes the impedance inverter 140, which may be implemented with a Pi -network, a T-network (shown in the example in FIGS. 1 and 2), or a quarter-wave transmission line. The components (e.g., inductors 142 and 144) of the impedance inverter 140 may be implemented with surface mount device (SMD) components. The SMD components may be placed on a substrate (e.g., a printed circuit board (PCB), a multi-layer laminate, or the like) of an RF front-end module. However, the SMD components take up space, which may increase the size and cost of the RF front-end module.

To address this, aspects of the present disclosure provide an output network for a Doherty PA including a shunt inductor coupled to the output of the main amplifier and a shunt capacitor coupled to the output of the auxiliary amplifier. The output network provides a more compact structure compared with an output network including the impedance inverter 140.

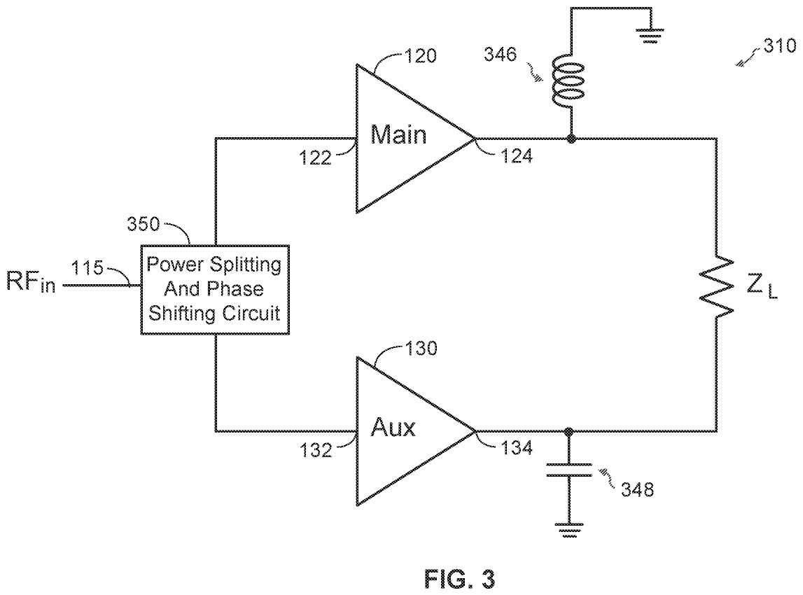

FIG. 3 shows an exemplary Doherty PA 310 according to aspects of the present disclosure. The Doherty PA 310 includes the main amplifier 120 and the auxiliary amplifier 130 discussed above. The Doherty PA 310 also includes a power splitting and phase shifting circuit 350 coupled to the input 115 of the Doherty PA 310, the input 122 of the main amplifier 120, and the input 132 of the auxiliary amplifier 130. The power splitting and phase shifting circuit 350 is configured to split the power of the RF signal (labeled “RF_{IN}”) at the input 115 between the main amplifier 120 and the auxiliary amplifier 130, and provide a phase shift θ between the input 122 of the main amplifier 120 and the input 132 of the auxiliary amplifier 130. For example, the power splitting and phase shifting circuit 350 may split the RF signal (labeled “RF_{IN}”) at the input 115 into a first RF signal and a second RF signal, output the first RF signal to the input 122 of the main amplifier 120, output the second RF signal to the input 132 of the auxiliary amplifier 130, and provide the phase shift θ between first RF signal and the second RF signal. The power splitting and phase shifting circuit 350 may be implemented with one or more power splitters and one or more phase shifters, as discussed further below.

Unlike the 90-degree phase shifter 150 shown in FIGS. 1 and 2, the phase shift θ provided by the power splitting and phase shifting circuit 350 can be different from 90 degrees. As discussed further below, the phase shift θ provides an additional design parameter that can be chosen to improve the power efficiency of the Doherty PA 310.

In the example in FIG. 3, the Doherty PA 310 includes a shunt inductor 346 coupled to the output 124 of the main amplifier 120. For example, the shunt inductor 346 may be coupled between the output 124 of the main amplifier 120 and ground (or some reference potential). The Doherty PA 310 also includes a shunt capacitor 348 coupled to the output 134 of the auxiliary amplifier 130. For example, the shunt capacitor 348 may be coupled between the output 134 of the auxiliary amplifier 130 and ground (or some reference potential). In this example, a differential load Z_{L} is coupled between the output 124 of the main amplifier 120 and the output 134 of the auxiliary amplifier 130. In certain aspects, the differential load Z_{L} may include a balun (e.g., a transformer), as discussed further below. In operation, the output RF signals of the main amplifier 120 and the auxiliary amplifier 130 are combined at the differential load Z_{L} using voltage combining.

An exemplary approach for choosing an inductance for the shunt inductor 346, a capacitance for the shunt capacitor 348, and a phase shift θ for the power splitting and phase shifting circuit 350 will now be discussed according to certain aspects.

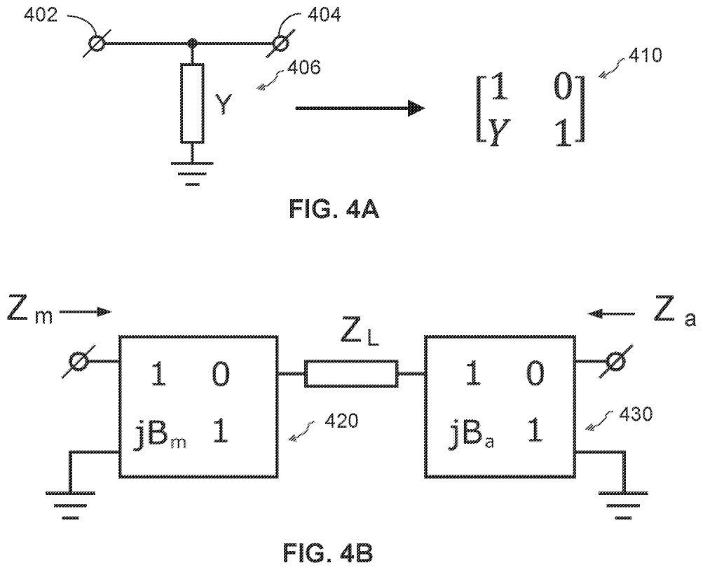

FIG. 4A shows an example of a shunt device 406 having an admittance of Y, in which the shunt device 406 is between a first port 402 and a second port 404. The shunt device 406 may be used to model a shunt inductor (e.g., the shunt inductor 346) or a shunt capacitor (e.g., the shunt capacitor 348). FIG. 4A also shows an example of an ABCD matrix 410 modeling the relationship between the voltage and the current at the first port 402 and the voltage and the current at the second port 404 in terms of the admittance Y of the shunt device 406.

FIG. 4B shows an exemplary mathematical model of the impedance Zₘ seen at the output 124 of the main amplifier 120 and the impedance Zₐ seen at the output 134 of the auxiliary amplifier 130 for the exemplary output network shown in FIG. 3. The model includes a first ABCD matrix 420 for the shunt inductor 346 where jBₘ is the susceptance of the shunt inductor 346 (i.e., imaginary part of admittance) and is a function of the inductance of the shunt inductor 346. The model includes a second ABCD matrix 430 for the shunt capacitor 348 where jBₐ is the susceptance of the shunt capacitor 348 (i.e., imaginary part of admittance) and is a function of the capacitance of the shunt capacitor 348. The model also include the impedance of the series differential load Z_{L} between the first ABCD matrix 420 and the second ABCD matrix 430.

In this example, the impedance Zₘ at the output 124 of the main amplifier 120 and the impedance Zₐ at the output 134 of the auxiliary amplifier 130 are a function of the inductance of the shunt inductor 346, the capacitance of the shunt capacitor 348, and the phase shift θ based on the exemplary model shown in FIG. 4B. Thus, the inductance of the shunt inductor 346, the capacitance of the shunt capacitor 348, and the phase shift θ provide design parameters that may be chosen to achieve target impedance values for Zₘ and Zₐ that provide high power efficiency over a wide range.

For example, the inductance of the shunt inductor 346, the capacitance of the shunt capacitor 348, and the phase shift θ may be chosen to achieve target impedance values for Zₘ and Zₐ that provide high power efficiency at the peak power and the back-off power of the Doherty PA 310. As discussed above, the Doherty PA 310 may have a first efficiency peak at the back-off power and a second efficiency peak at the peak power.

For example, a target impedance value for Zₘ and a target impedance value for Zₐ that provide high power efficiency at the peak power of the Doherty PA 310 may be determined. Also, a target impedance value for Zₘ and a target impedance value for Zₐ that provide high power efficiency at the back-off power (e.g., 6 dB below the peak power) of the Doherty PA 310 may be determined. The target impedance values may be determined, for example, using a computer simulator that simulates power efficiency at the peak power and the back-off power as a function of the impedance values for Zₘ and Zₐ. After the target impedances values are determined, an inductance of the shunt inductor 346, a capacitance of the shunt capacitor 348, and a phase shift θ may be chosen to achieve the target impedance values (e.g., based on the exemplary model shown in FIG. 4B).

In the above examples, the phase shift θ provides an additional degree of freedom in achieving the target impedance values for Zₘ and Zₐ. In contrast, in the examples in FIGS. 1 and 2, the phase shift of the 90-degree phase shifter 150 is fixed at 90 degrees and is not used as a design parameter for achieving target impedance values for Zₘ and Zₐ. Since the phase shift θ of the power splitting and phase shifting circuit 350 is a design parameter that is not fixed at 90 degrees, the phase shift θ may be different from 90 degrees. For example, the phase shift θ may be within a range between 100 degrees and 180 degrees to achieve the target impedance values. However, it is to be appreciated that the phase shift θ is not limited to a phase shift within this exemplary range.

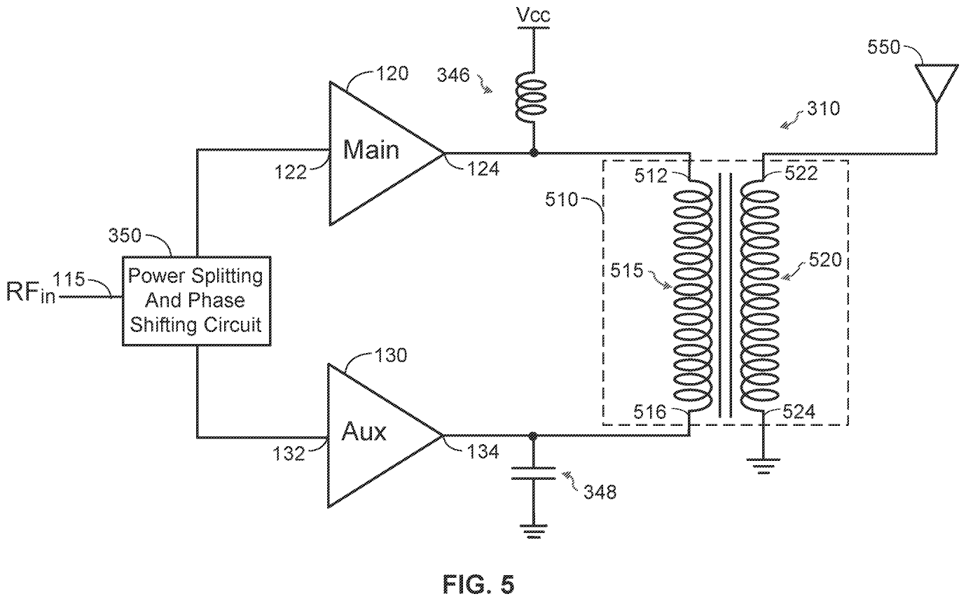

FIG. 5 shows an example in which the differential load Z_{L} is a transformer 510. The transformer 510 may be used as a balun to convert the differential RF signal of the Doherty PA 310 into a single-ended RF signal, as discussed further below.

In this example, the transformer 510 includes a first inductor 515 and a second inductor 520 magnetically (i.e., inductively) coupled with the first inductor 515. The first inductor 515 may also be referred to as a primary inductor or winding, and the second inductor 520 may also be referred to as secondary inductor or winding. Each of the inductors 515 and 520 may be implemented with two or more inductors coupled in series and/or parallel. The first inductor 515 has a first terminal 512 coupled to the output 124 of the main amplifier 120, and a second terminal 516 coupled to the output 134 of the auxiliary amplifier 130. The second inductor 520 has a first terminal 522 coupled to an antenna 550, and a second terminal 524 coupled to ground (or some reference potential). It should be appreciated that in some implementations one or more elements or components may be coupled between the second inductor 520 and the antenna such as a filter (e.g., RF filter such as a microacustic filter), an antenna tuner, and the like.

In operation, the output RF signals of the main amplifier 120 and the auxiliary amplifier 130 are combined at the transformer 510 through voltage combining, and the resulting combined RF signal is output to the antenna 550 for transmission. The voltage combining provides a wider bandwidth compared with current combining at a shunt load. This is because the voltage combining provides the transformer 510 with a larger impedance at the second inductor 520, which provides better impedance matching with the load impedance (e.g., 50 Ohm) coupled to the second inductor 520. The load impedance may come from the antenna 550, and/or a transmission line coupling the antenna 550 to the transformer 510.

In the example shown in FIG. 5, the shunt inductor 346 is coupled between the output 124 of the main amplifier 120 and a supply rail providing a supply voltage Vcc. In this example, the supply voltage Vcc provides DC biasing for the main amplifier 120 through the shunt inductor 346 and DC biasing for the auxiliary amplifier 130 through the shunt inductor 346 and the first inductor 515 of the transformer 510. The supply rail may act as an AC ground for RF signals.

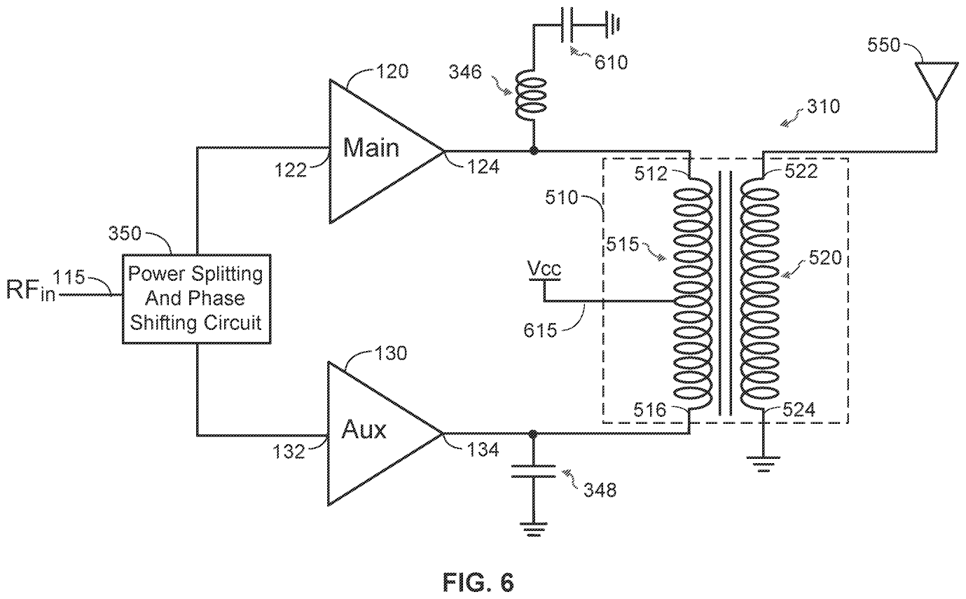

FIG. 6 shows another example in which the Doherty PA 310 includes a tap 615 coupling the supply rail (which provides supply voltage Vcc) to the first inductor 515 of the transformer 510. In this example, DC biasing for the main amplifier 120 and the DC biasing for the auxiliary amplifier 130 are provided by the supply rail coupled to the tap 615. In some implementations, the tap 615 may be a center tap coupled to the center of the first inductor 515. However, it is to be appreciated that the tap 615 is not limited to the center of the first inductor 515 and that the tap 615 may be coupled to other locations on the first inductor 515 (i.e., the length between the first terminal 512 and the tap 615 may be different from the length between the tap 615 and the second terminal 516).

In the example in FIG. 6, the Doherty PA 310 also includes a coupling capacitor 610 coupled between the shunt inductor 346 and ground. The coupling capacitor 610 is used to block DC voltages (e.g., the supply voltage Vcc from the supply rail) while providing an AC short to ground for RF signals.

It is to be appreciated that the present disclosure is not limited to the examples shown in FIGS. 5 and 6, and that the main amplifier 120 and the auxiliary amplifier 130 may be DC biased using other techniques.

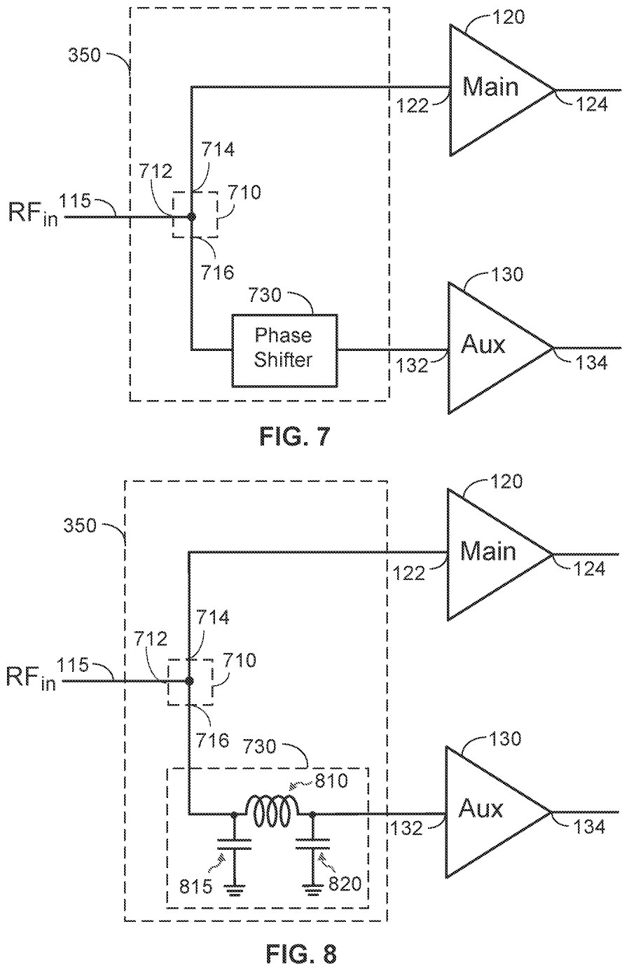

FIG. 7 shows an exemplary implementation of the power splitting and phase shifting circuit 350 according to certain aspects. In this example, the power splitting and phase shifting circuit 350 includes a power splitter 710 and a phase shifter 730. The power splitter 710 has input 712 coupled to the input 115, a first output 714, and a second output 716. In this example, the power splitter 710 is implemented with conductive routing (e.g., metal routing) that splits into a first branch providing the first output 714 and a second branch providing the second output 716. In this example, the power splitting and phase shifting circuit 350 splits the RF signal (labeled “RF_{IN}”) at the input 115 into the first RF signal at the first output 714 and the second RF signal at the second output 716.

In this example, the first output 714 of the power splitter 710 is coupled to the input 122 of the main amplifier 120, and the phase shifter 730 is coupled between the second output 716 of the power splitter 710 and the input 132 of the auxiliary amplifier 130. The phase shifter 730 may be configured to shift the phase of the second RF signal by the phase shift θ before inputting the second RF signal to the auxiliary amplifier 130. Although one phase shifter is shown in the example in FIG. 7, it is to be appreciated that the power splitting and phase shifting circuit 350 may include more than one phase shifter, as discussed further below.

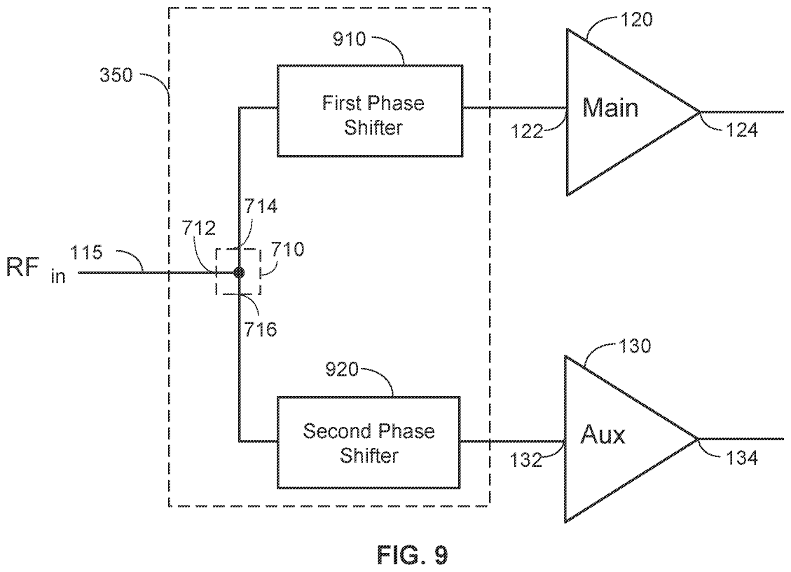

FIG. 8 shows an exemplary implementation of the phase shifter 730. In this example, the phase shifter 730 includes a series inductor 810 and shunt capacitors 815 and 820. In this example, the inductance of the series inductor 810 and the capacitances of the shunt capacitors 815 and 820 may be chosen to achieve the desired phase shift θ. It is to be appreciated that the phase shifter 730 is not limited to the exemplary implementation shown in FIG. 8.

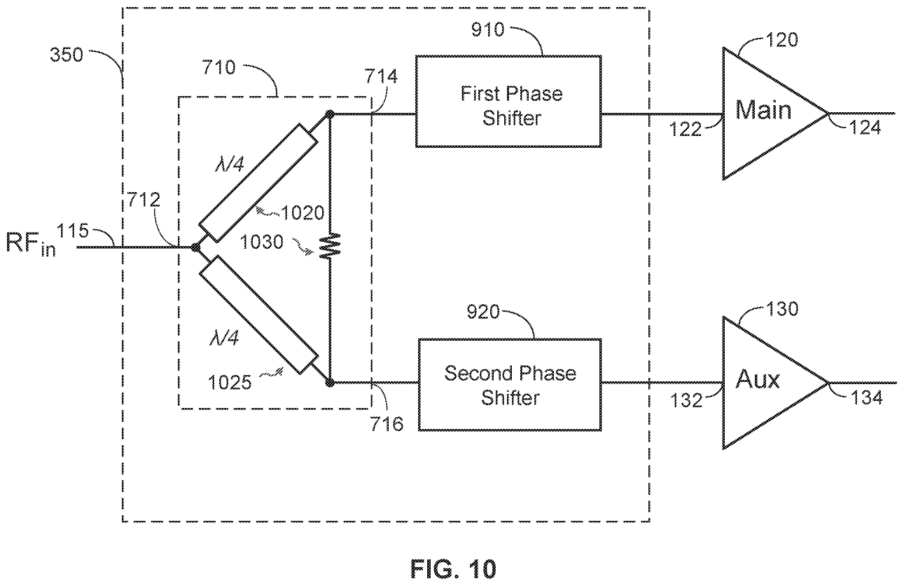

FIG. 9 shows another exemplary implementation of the power splitting and phase shifting circuit 350 according to certain aspects. In this example, power splitting and phase shifting circuit includes a first phase shifter 910 and a second phase shifter 920. The first phase shifter 910 is between coupled between the first output 714 of the power splitter 710 and the input 122 of the main amplifier 120, and the second phase shifter 920 is coupled between the second output 716 of the power splitter 710 and the input 132 of the auxiliary amplifier 130.

In this example, the first phase shifter 910 is configured to shift the phase of the first RF signal by a first phase shift before the first RF signal is input to the main amplifier 120, and the second phase shifter 920 is configured to shift the phase of the second RF signal by a second phase shift before the second RF signal is input to the auxiliary amplifier 130. The first phase shift of the first phase shifter 910 and the second phase shift of the second phase shifter 920 may be chosen such that the phase shift between the first RF signal at the input 122 of the main amplifier 120 and the second RF signal at the input of the 132 of the auxiliary amplifier 130 is equal to the phase shift θ discussed above. Thus, the phase shift θ between the input 122 of the main amplifier 120 and the input 132 of the auxiliary amplifier 130 is achieved using the first phase shifter 910 and the second phase shifter 920 in combination in this example. In other words, each of the first phase shifter 910 and the second phase shifter 920 contribute to the phase shift θ between the first RF signal and the second RF signal.

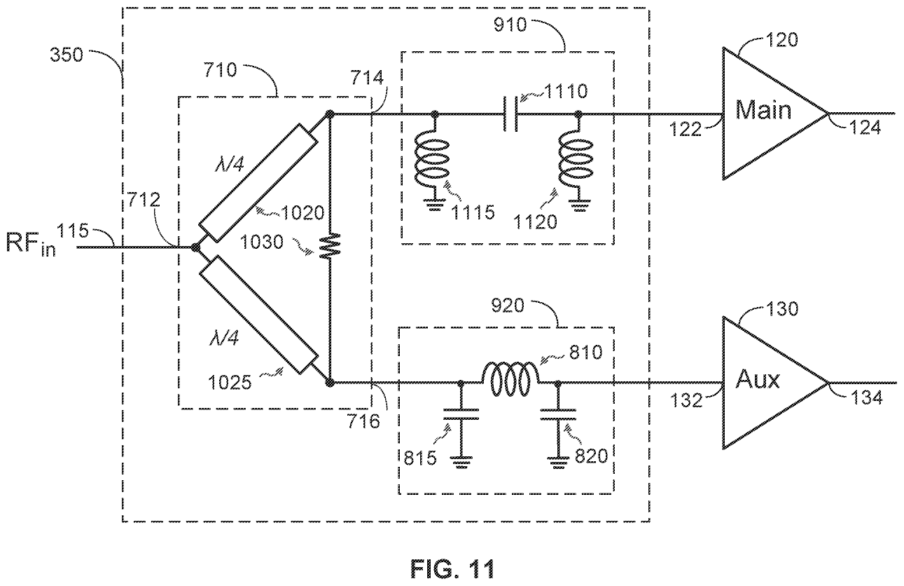

FIG. 10 shows another exemplary implementation of the power splitting and phase shifting circuit 350 according to certain aspects. In this example, the power splitter 710 is implemented with a Wilkinson power splitter. However, it is to be appreciated that the power splitter 710 (also referred to as a power divider) is not limited to a Wilkinson power splitter.

In the example in FIG. 10, the power splitter 710 includes a first quarter-wavelength transmission line 1020 coupled between the input 712 and the first output 714, a second quarter-wavelength transmission line 1025 coupled between the input 712 and the second output 716, and a resistor 1030 coupled between the first output 714 and the second output 716. In this example, the power splitter 710 is configured to receive the input RF signal (labeled “RF_{IN}”) at the input 712, split the input RF signal into the first RF signal and the second RF signal, output the first RF signal at the first output 714, and output the second RF signal at the second output 716.

It is to be appreciated that the power splitting and phase shifting circuit 350 is not limited to the example shown in FIG. 10. For example, in some implementations, the first output 714 of the power splitter 710 may be coupled to the input 122 of the main amplifier 120 with the first phase shifter 910 omitted. In this example, the phase shifter 730 may be coupled between the second output 716 of the power splitter 710 and the input 132 of the auxiliary amplifier 130 to provide the phase shift θ.

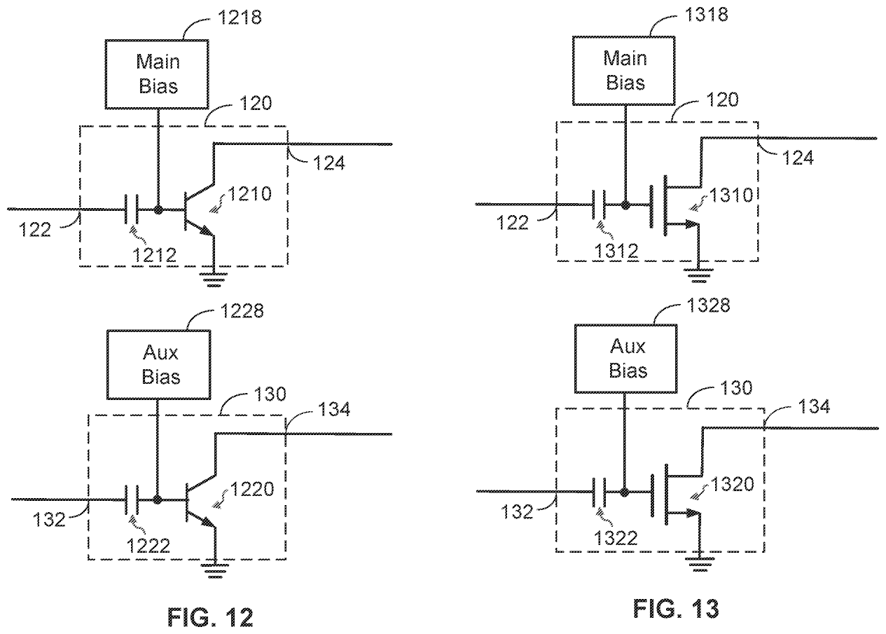

FIG. 11 shows an exemplary implementation of the first phase shifter 910 and the second phase shifter 920 according to certain aspects. In this example, the first phase shifter 910 includes a series capacitor 1110 and shunt inductors 1115 and 1120. The second phase shifter 920 includes the series inductor 810 and the shunt capacitors 815 and 820 shown in the example in FIG. 8. In this example, the inductances of the inductors 810, 1115, and 1120 and the capacitances of the capacitors 815, 820, and 1110 may be chosen to achieve the desired phase shift θ between the input 122 of the main amplifier 120 and the input 132 of the auxiliary amplifier 130. It is to be appreciated that the first phase shifter 910 and the second phase shifter 920 are not limited to the exemplary implementation shown in FIG. 11.

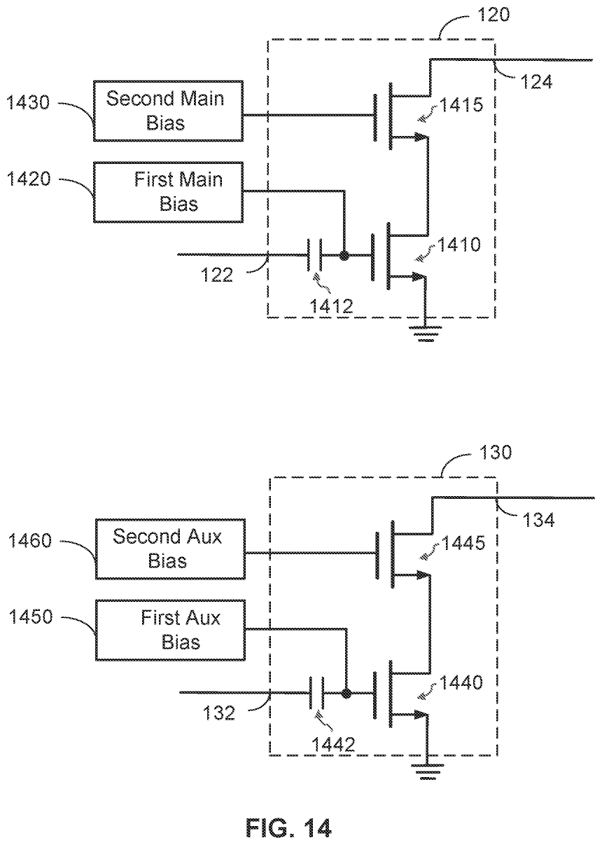

FIG. 12 shows an exemplary implementation of the main amplifier 120 and the auxiliary amplifier 130 according to certain aspects. In this example, the main amplifier 120 includes a first bipolar junction transistor (BJT) 1210 and a first coupling capacitor 1212. The collector of the first BJT 1210 is coupled to the output 124 of the main amplifier 120, and the emitter of the first BJT 1210 is coupled to ground (or some reference potential). The base of the first BJT 1210 is coupled to a main bias circuit 1218 configured to bias the base of the first BJT 1210. The first coupling capacitor 1212 is coupled between the input 122 of the main amplifier 120 and the base of the first BJT 1210. The first coupling capacitor 1212 is configured to couple the RF signal at the input 122 to the base of the first BJT 1210 while blocking the bias voltage from the main bias circuit 1218. The collector of the first BJT 1210 may be biased by the supply voltage Vcc in FIG. 5 or FIG. 6.

In this example, the auxiliary amplifier 130 includes a second BJT 1220 and a second coupling capacitor 1222. The collector of the second BJT 1220 is coupled to the output 134 of the auxiliary amplifier 130, and the emitter of the second BJT 1220 is coupled to ground (or some reference potential). The base of the second BJT 1220 is coupled to an auxiliary bias circuit 1228 configured to bias the base of the second BJT 1220. For example, the auxiliary bias circuit 1228 may be configured to bias the second BJT 1220 in Class C. The second coupling capacitor 1222 is coupled between the input 132 of the auxiliary amplifier 130 and the base of the second BJT 1220. The second coupling capacitor 1222 is configured to couple the RF signal at the input 132 to the base of the second BJT 1220 while blocking the bias voltage from the auxiliary bias circuit 1228. The collector of the second BJT 1220 may be biased by the supply voltage Vcc in FIG. 5 or FIG. 6.

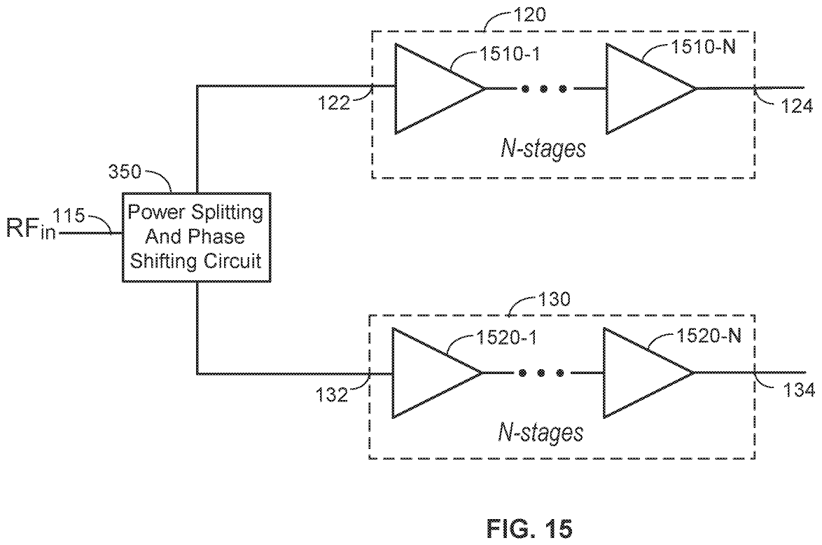

FIG. 13 shows another exemplary implementation of the main amplifier 120 and the auxiliary amplifier 130 according to certain aspects. In this example, the main amplifier 120 includes a first field effect transistor (FET) 1310 and a first coupling capacitor 1312. The drain of the first FET 1310 is coupled to the output 124 of the main amplifier 120, and the source of the first FET 1310 is coupled to ground (or some reference potential). The gate of the first FET 1310 is coupled to a main bias circuit 1318 configured to bias the gate of the first FET 1310. The first coupling capacitor 1312 is coupled between the input 122 of the main amplifier 120 and the gate of the first FET 1310. The first coupling capacitor 1312 is configured to couple the input RF signal from the input 122 to the gate of the first FET 1310 while blocking the bias voltage from the main bias circuit 1318. The drain of the first FET 1310 may be biased by the supply voltage Vcc in FIG. 5 or FIG. 6.

In this example, the auxiliary amplifier 130 includes a second FET 1320 and a second coupling capacitor 1322. The drain of the second FET 1320 is coupled to the output 134 of the auxiliary amplifier 130, and the source of the second FET 1320 is coupled to ground (or some reference potential). The gate of the second FET 1320 is coupled to an auxiliary bias circuit 1328 configured to bias the gate of the second FET 1320. For example, the auxiliary bias circuit 1328 may be configured to bias the second FET 1320 in Class C. The second coupling capacitor 1322 is coupled between the input 132 of the auxiliary amplifier 130 and the gate of the second FET 1320. The second coupling capacitor 1322 is configured to couple the input RF signal at the input 132 to the gate of the second FET 1320 while blocking the bias voltage from the auxiliary bias circuit 1328. The drain of the second FET 1320 may be biased by the supply voltage Vcc in FIG. 5 or FIG. 6.

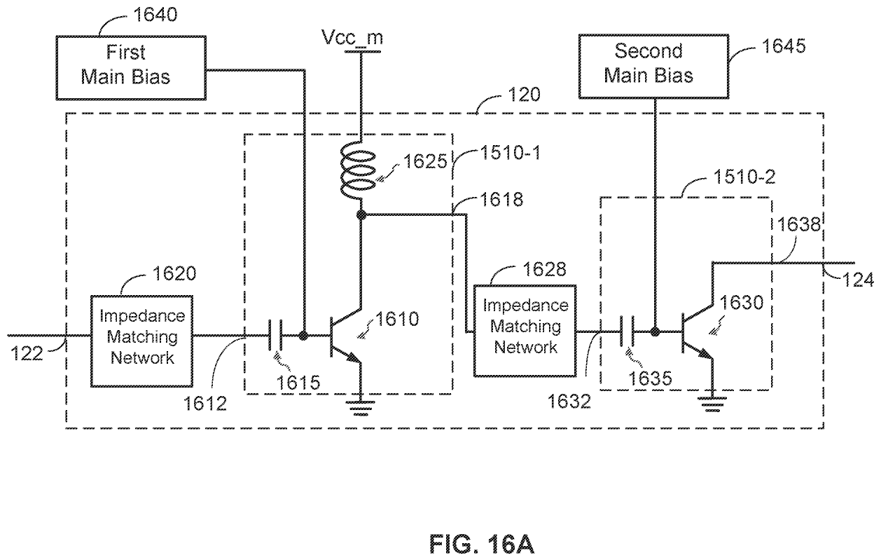

FIG. 14 shows another exemplary implementation of the main amplifier 120 and the auxiliary amplifier 130 according to certain aspects. In this example, the main amplifier 120 is implemented with a cascode amplifier including a first FET 1410, a second FET 1415, and the first coupling capacitor 1412. The drain of the second FET 1415 is coupled to the output 124 of the main amplifier 120. The drain of the first FET 1410 is coupled to the source of the second FET 1415 and the source of the first FET 1410 is coupled to ground (or some reference potential). The gate of the first FET 1410 is coupled to a first main bias circuit 1420 configured to bias the gate of the first FET 1410. The first coupling capacitor 1412 is coupled between the input 122 of the main amplifier 120 and the gate of the first FET 1410. The first coupling capacitor 1412 is configured to couple the input RF signal at the input 122 to the gate of the first FET 1410 while blocking the bias voltage from the first main bias circuit 1420. The gate of the second FET 1415 is coupled to a second main bias circuit 1430 configured to bias the gate of the second FET 1415. In this example, the second FET 1415 functions as a common gate amplifier. The drain of the second FET 1415 may be biased by the supply voltage Vcc in FIG. 5 or FIG. 6.

In this example, the auxiliary amplifier 130 is implemented with a cascode amplifier including a third FET 1440, a fourth FET 1445, and the second coupling capacitor 1442. The drain of the fourth FET 1445 is coupled to the output 134 of the auxiliary amplifier 130. The drain of the third FET 1440 is coupled to the source of the fourth FET 1445 and the source of the third FET 1440 is coupled to ground (or some reference potential). The gate of the third FET 1440 is coupled to a first auxiliary bias circuit 1450 configured to bias the gate of the third FET 1440 in Class C. The second coupling capacitor 1442 is coupled between the input 132 of the auxiliary amplifier 130 and the gate of the third FET 1440. The second coupling capacitor 1442 is configured to couple the input RF signal at the input 132 to the gate of the third FET 1440 while blocking the bias voltage from the first auxiliary bias circuit 1450. The gate of the fourth FET 1445 is coupled to a second auxiliary bias circuit 1460 configured to bias the gate of the fourth FET 1445. In this example, the fourth FET 1445 functions as a common gate amplifier. The drain of the fourth FET 1445 may be biased by the supply voltage Vcc in FIG. 5 or FIG. 6.

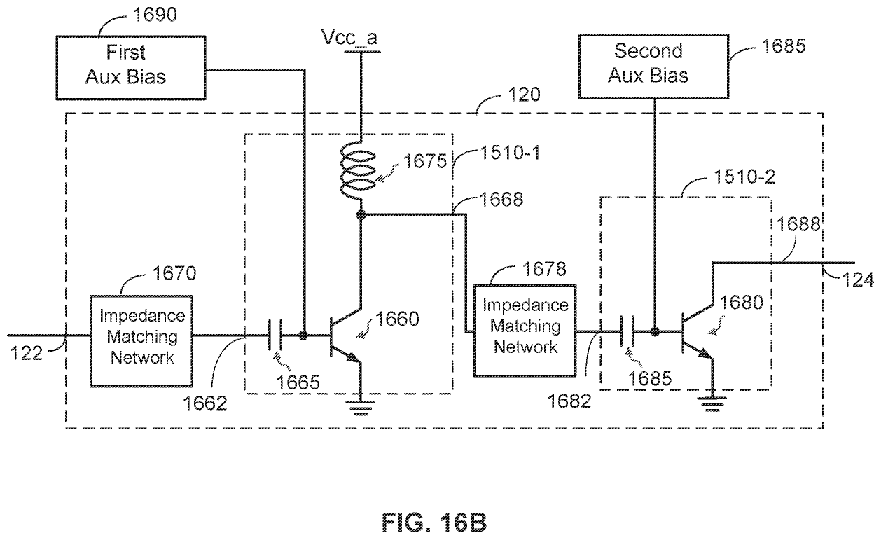

It is to be appreciated that the main amplifier 120 and the auxiliary amplifier 130 may each be implemented with multi-stage amplifiers in some implementations. In this regard, FIG. 15 shows an example in which the main amplifier 120 includes two or more stages 1510-1 to 1510-n and the auxiliary amplifier 130 includes two or more stages 1520-1 to 1520-according to certain aspects.

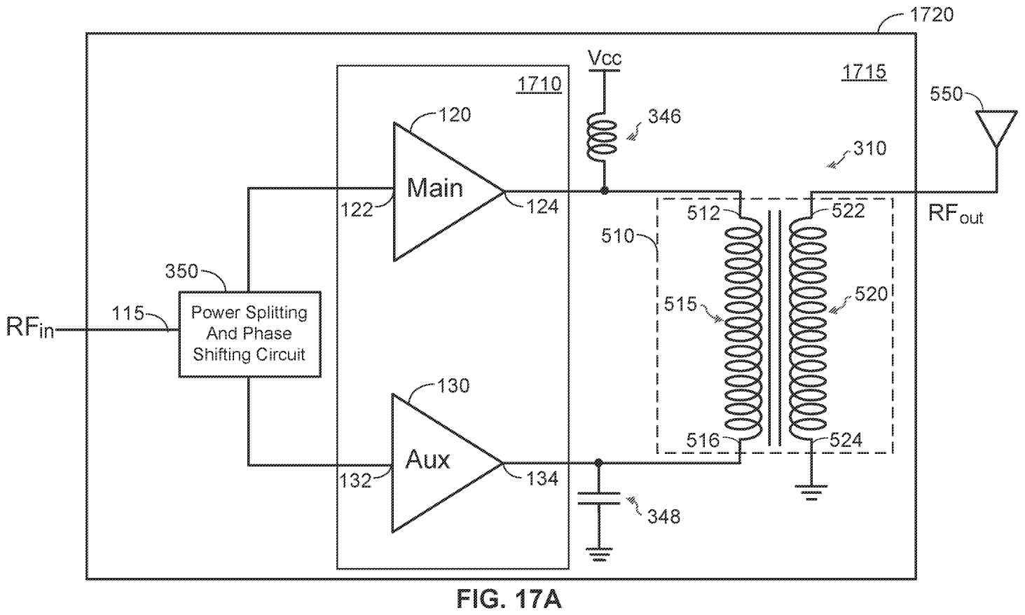

FIGS. 16A and 16B show an exemplary implementation in which the main amplifier 120 includes a first stage 1510-1 and a second stage 1510-2, and the auxiliary amplifier 130 includes a first stage 1520-1 and a second stage 1520-2 according to certain aspects. Referring to FIG. 16A, the first stage 1510-1 includes a first BJT 1610, a first coupling capacitor 1615 coupled between the input 1612 of the first stage 1510-1 and the base of the first BJT 1610, and a load inductor 1625 coupled between a supply rail and the collector of the first BJT 1610. The supply rail provides a supply voltage Vcc_m which may be the same as the supply voltage Vcc or different. The emitter of the first BJT 1610 is coupled to ground (or some reference potential) and the output 1618 of the first stage 1510-1 is taken between the collector of the first BJT 1610 and the load inductor 1625. The input 1612 is coupled to the input 122 of the main amplifier 120 via a first impedance matching network 1620, and the base of the first BJT 1610 is biased by a first main bias circuit 1640.

The second stage 1510-2 includes a second BJT 1630 and a second coupling capacitor 1635 coupled between the input 1632 of the second stage 1510-2 and the base of the second BJT 1630. The emitter of the second BJT 1630 is coupled to ground (or some reference potential), the collector of the second BJT 1630 is coupled to the output 1638 of the second stage 1510-2, and the base of the second BJT 1630 is biased by a second main bias circuit 1645. The input 1632 is coupled to the output 1618 of the first stage 1510-1 via a second impedance matching network 1628.

Referring to FIG. 16B, the first stage 1520-1 includes a first BJT 1660, a first coupling capacitor 1665 coupled between the input 1662 of the first stage 1520-1 and the base of the first BJT 1660, and a load inductor 1675 coupled between a supply rail and the collector of the first BJT 1660. The supply rail provides a supply voltage Vcc_a which may be the same as the supply voltage Vcc or different. The emitter of the first BJT 1660 is coupled to ground (or some reference potential) and the output 1668 of the first stage 1520-1 is taken between the collector of the first BJT 1660 and the load inductor 1675. The input 1662 is coupled to the input 132 of the auxiliary amplifier 130 via a first impedance matching network 1670, and the base of the first BJT 1660 is biased by a first auxiliary bias circuit 1690.

The second stage 1520-2 includes a second BJT 1680 and a second coupling capacitor 1685 coupled between the input 1682 of the second stage 1520-2 and the base of the second BJT 1680. The emitter of the second BJT 1680 is coupled to ground (or some reference potential), the collector of the second BJT 1680 is coupled to the output 1688 of the second stage 1520-2, and the base of the second BJT 1680 is biased by a second auxiliary bias circuit 1695. The input 1682 is coupled to the output 1668 of the first stage 1520-1 via a second impedance matching network 1678.

It is to be appreciated that the main amplifier 120 and the auxiliary amplifier 130 may also be implemented with multiple stages including FETs.

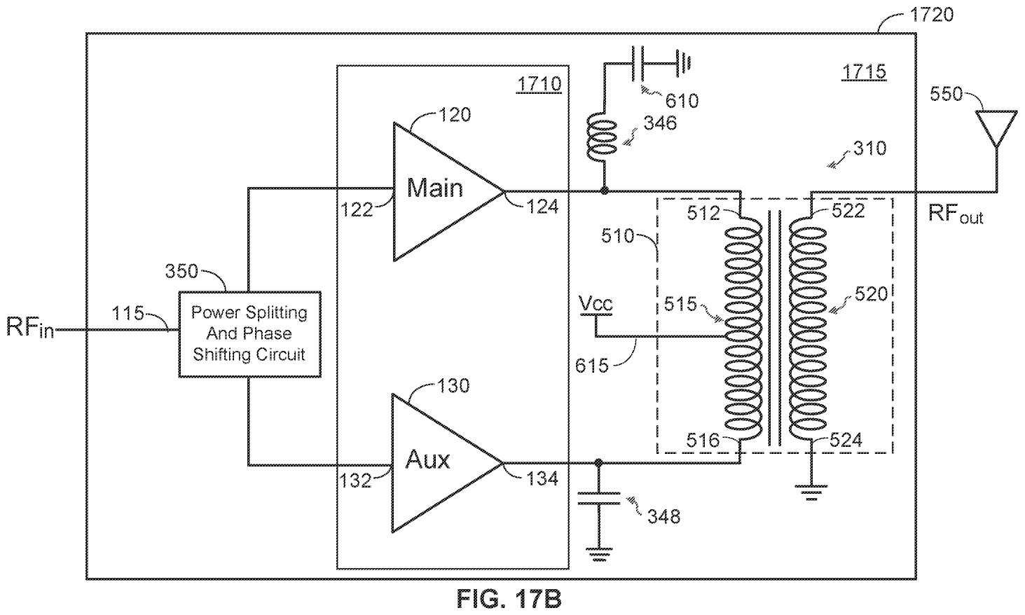

FIG. 17A shows an example of an RF front-end module 1720 including the Doherty PA 310 according to certain aspects. In this example, the RF front-end module 1720 includes a substrate 1715 (e.g., PCB) and a die 1710 (e.g., GaAs die, silicon die, etc.) mounted on the substrate 1715 (e.g., flip-chip mounted on the substrate 1715). The die 1710 includes the main amplifier 120 and the auxiliary amplifier 130. For example, for the exemplary implementation where the main amplifier 120 and the auxiliary amplifier 130 include the first BJT 1210 and the second BJT 1220, respectively, the die 1710 includes the first BJT 1210 and the second BJT 1220. For the exemplary implementation where the main amplifier 120 and the auxiliary amplifier 130 include the first FET 1310 and the second FET 1320, respectively, the die 1710 includes the first FET 1310 and the second FET 1320. An RF front-end module may also be referred to as an RFFE module or RFFE circuit.

In the example in FIG. 17A, the shunt inductor 346, the shunt capacitor 348, and transformer 510 may be placed on the substrate 1715 and/or embedded in the substrate 1715. Although the transformer 510 is shown as being part of the RF front-end module 1720 in the example in FIG. 17A, it is to be appreciated that the transformer 510 may be located outside of the RF front-end module 1720 is some implementations.

In the example in FIG. 17A, the main amplifier 120 and the auxiliary amplifier 130 are biased by the supply rail through the shunt inductor 346. FIG. 17B shows another example of the RF front-end module 1720 in which the main amplifier 120 and the auxiliary amplifier 130 are biased by the supply rail through the tap 615 of the first inductor 515 of the transformer 510.

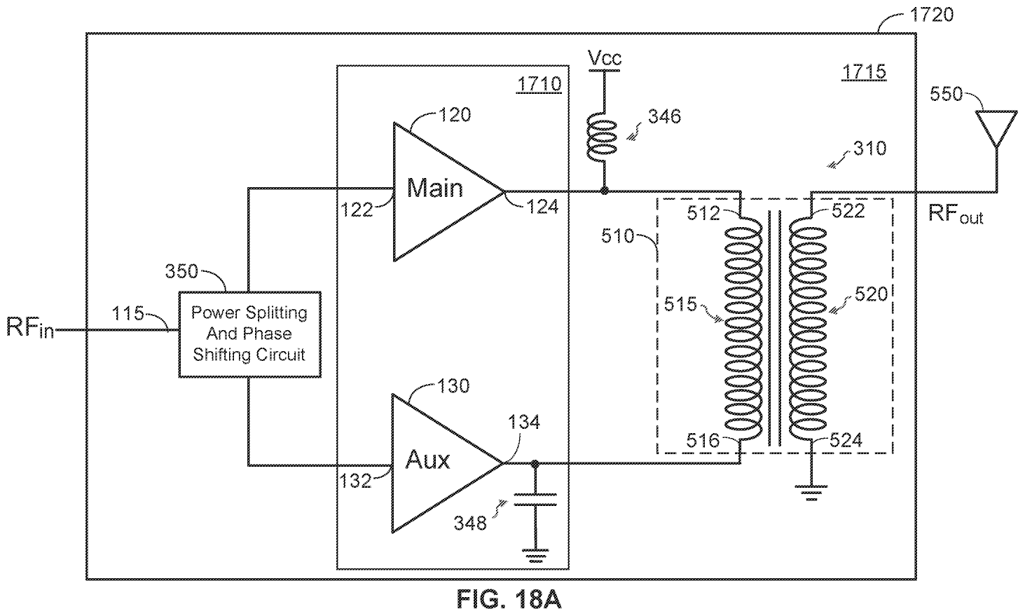

FIG. 18A shows an example of the exemplary implementation of the RF front-end module 1720 of FIG. 17A in which the shunt capacitor 348 is integrated on the die 1710 with the auxiliary amplifier 130. FIG. 18B shows an example of the exemplary implementation of the RF front-end module 1720 of FIG. 17B in which the shunt capacitor 348 is integrated on the die 1710. It is to be appreciated that, in each of the examples shown in FIGS. 18A and 18B, the die 1710 may also include an integrated shunt capacitor (not shown) coupled to the output 124 of the main amplifier 120.

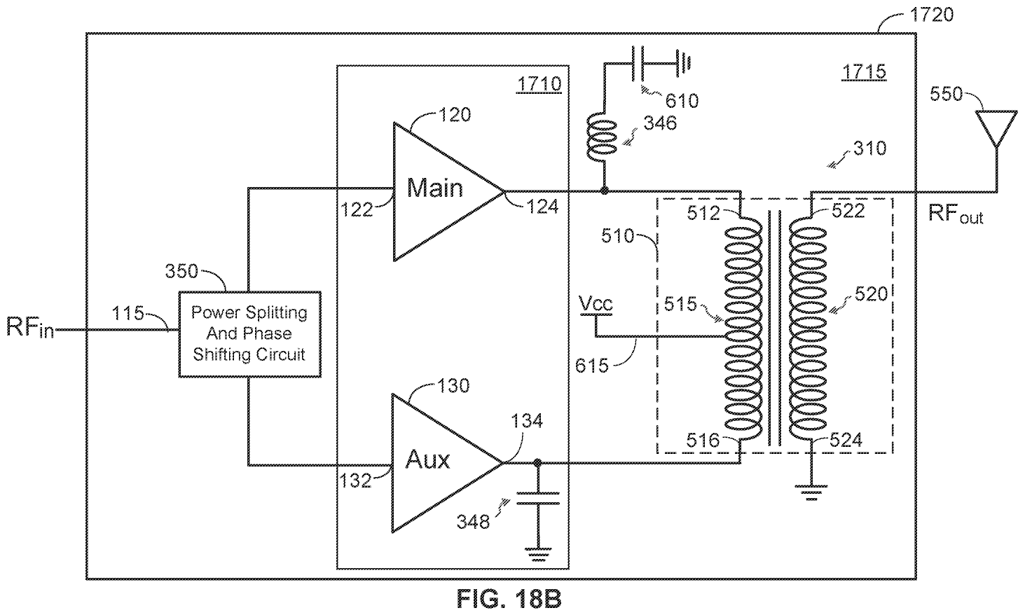

FIG. 19 shows an example in which the Doherty PA 310 also includes a first capacitor 1910 coupled in parallel with the first inductor 515 of the transformer 510, and a second capacitor 1915 coupled in parallel with the second inductor 520 of the transformer 510. In this example, the capacitances of the capacitors 1910 and 1915 may be chosen to enhance the transfer of power from the first inductor 515 to the second inductor 520 for a desired center frequency of the output RF signal. In some implementations, one of the capacitors 1910 and 1915 may be omitted.

FIG. 19 also shows an example of a third capacitor 1920 coupled between a tap 1922 on the first inductor 515 of the transformer 510 and ground to provide an AC short to ground. The tap 1922 may be a center tap located at the center of the first inductor 515 or a tap located at another location on the first inductor 515.

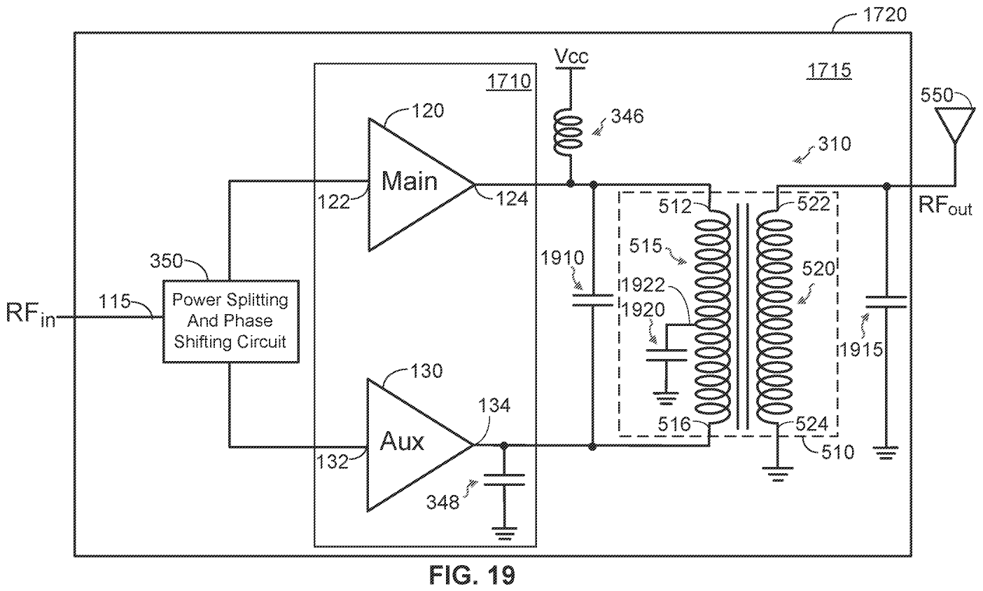

FIG. 20 shows an exemplary implementation of the transformer 510 according to certain aspects. In this example, the first inductor 515 is implemented with a first planar loop inductor formed from a first metal layer (e.g., using a lithographic and etching process). The left half of FIG. 20 shows a top view of the first inductor 515 without the second inductor 520.

In this example, the second inductor 520 is implemented with a second planar loop inductor formed from a second metal layer (e.g., using a lithographic and etching process). The second metal layer may be above or below the first metal layer with an insulating layer interposed between the first metal layer and the second metal layer. For the exemplary RF front-end module 1720, the first metal layer and the second metal layer may be placed on the substrate 1715 and/or embedded in the substrate 1715.

The right half of FIG. 20 shows a top view of an example in which the second inductor 520 overlaps the first inductor 515 to form the transformer 510. In this example, the overlap of the first inductor 515 and the second inductor 520 provides the magnetic (i.e., inductive) coupling between the first inductor 515 and the second inductor 520.

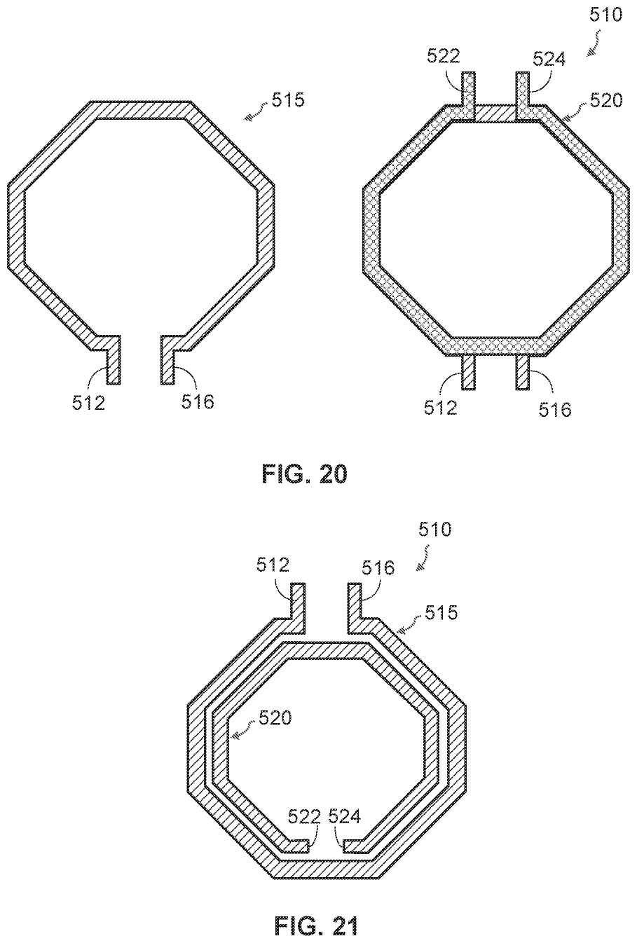

In the example in FIG. 20, the first inductor 515 and the second inductor 520 are formed from different metal layers. FIG. 21 shows another exemplary implementation in which the first inductor 515 and the second inductor 520 are formed from the same metal layer. In this example, the first inductor 515 is implemented with a first planar loop inductor and the second inductor 520 is implemented with a second planar inductor. The second inductor 520 is located within the inner loop of the first inductor 515 to provide the magnetic (i.e., inductive) coupling between the first inductor 515 and the second inductor 520.

Although not shown in FIGS. 20 and 21, it is to be appreciated that the first inductor 515 may include the tap 615 extending from a location (e.g., center location) on the first inductor 515.

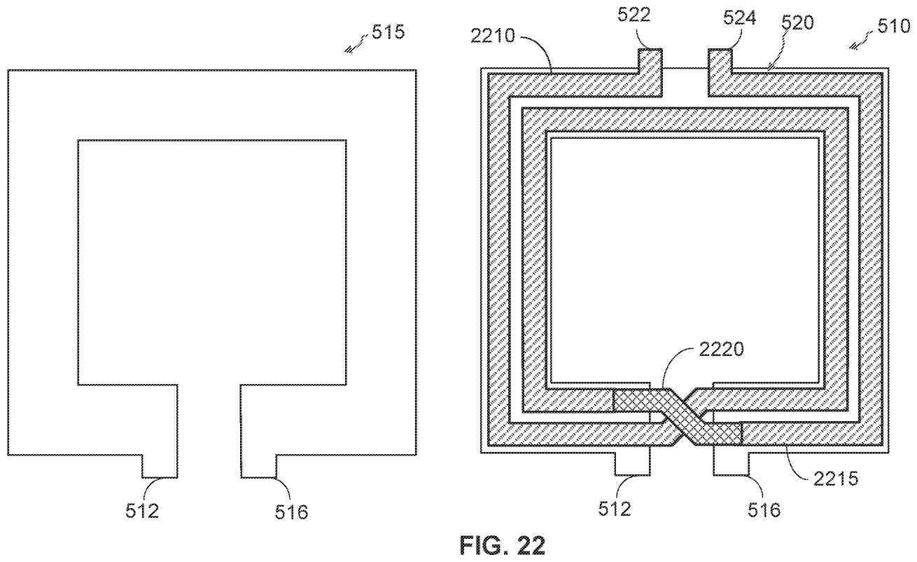

FIG. 22 shows another exemplary implementation of the transformer 510 in which the transformer has a turn ratio higher than 1:1 according to certain aspects. In this example, the first inductor 515 is implemented with a first planar loop inductor formed from a first metal layer (e.g., using a lithographic and etching process). The left half of FIG. 22 shows a top view of the first inductor 515 without the second inductor 520.

In this example, the second inductor 520 has two turns for a turn ratio of 1:2. The second inductor 520 includes first portion 2210 and a second portion 2215 formed from a second metal layer (e.g., using a lithographic and etching process), and a bridge 2220 formed from a third metal layer (e.g., using a lithographic and etching process). The bridge 2220 crosses over the first portion 2210 and is coupled to the first portion 2210 and the second portion 2215 by vias (not shown) between the second metal layer and the third metal layer.

The right half of FIG. 22 shows a top view of an example in which the second inductor 520 overlaps the first inductor 515 to form the transformer 510. In this example, the overlap of the first inductor 515 and the second inductor 520 provides the magnetic (i.e., inductive) coupling between the first inductor 515 and the second inductor 520.

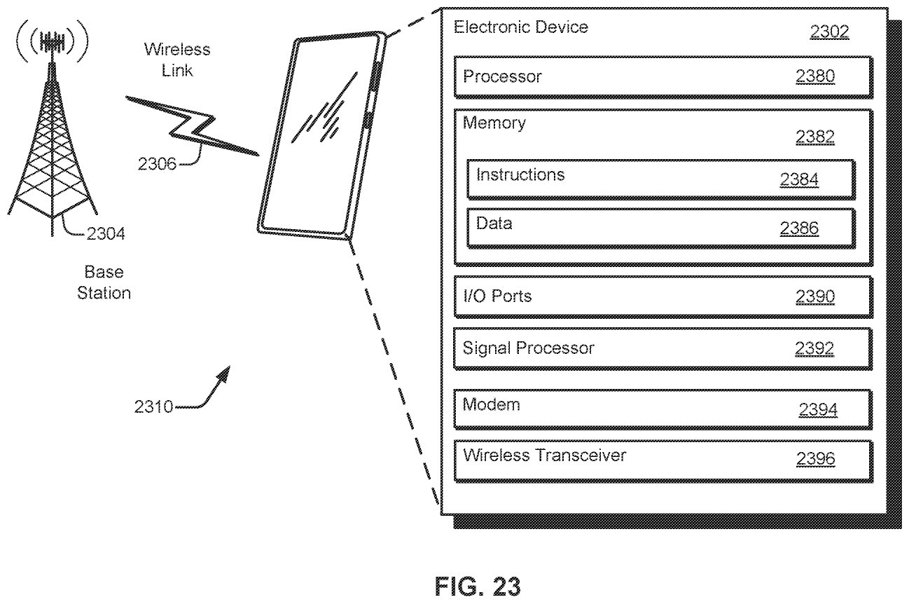

FIG. 23 is a diagram of an environment 2300 that includes an electronic device 2302 and a base station 2304. The electronic device 2302 includes a wireless transceiver 2396, which may include the Doherty PA 310.

In the environment 2300, the electronic device 2302 communicates with the base station 2304 through a wireless link 2306. As shown, the electronic device 2302 is depicted as a smart phone. However, the electronic device 2302 may be implemented as any suitable computing or other electronic device, such as a cellular base station, a broadband router, an access point, a cellular or mobile phone, a gaming device, a navigation device, a media device, a laptop computer, a desktop computer, a tablet computer, a server computer, a network-attached storage (NAS) device, a smart appliance, a vehicle-based communication system, an Internet of Things (IoT) device, a sensor or security device, an asset tracker, and so forth.

The base station 2304 communicates with the electronic device 2302 via the wireless link 2306, which may be implemented as any suitable type of wireless link. Although depicted as a base station tower of a cellular radio network, the base station 2304 may represent or be implemented as another device, such as a satellite, a terrestrial broadcast tower, an access point, a peer-to-peer device, a mesh network node, a fiber optic line, another electronic device generally as described above, and so forth. Hence, the electronic device 2302 may communicate with the base station 2304 or another device via a wired connection, a wireless connection, or a combination thereof. The wireless link 2306 can include a downlink of data or control information communicated from the base station 2304 to the electronic device 2302 and an uplink of other data or control information communicated from the electronic device 2302 to the base station 2304. The wireless link 2306 may be implemented using any suitable communication protocol or standard, such as 3rd Generation Partnership Project Long-Term Evolution (3GPP LTE, 3GPP NR 5G), IEEE 2302.11, IEEE 2302.11, Bluetooth™, and so forth.

The electronic device 2302 includes a processor 2380 and a memory 2382. The memory 2382 may be or form a portion of a computer readable storage medium. The processor 2380 may include any type of processor, such as an application processor or a multi-core processor, that is configured to execute processor-executable instructions (e.g., code) stored by the memory 2382. The memory 2382 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 2382 is implemented to store instructions 2384, data 2386, and other information of the electronic device 2302.

The electronic device 2302 may also include input/output (I/O) ports 2390. The I/O ports 2390 enable data exchanges or interaction with other devices, networks, or users or between components of the device.

The electronic device 2302 may further include a signal processor (SP) 2392 (e.g., such as a digital signal processor (DSP)). The signal processor 2392 may function similar to the processor 2380 and may be capable of executing instructions and/or processing information in conjunction with the memory 2382.

For communication purposes, the electronic device 2302 also includes a modem 2394, the wireless transceiver 2396 (e.g., the Doherty PA 310 and/or the RF front-end module 1720), and one or more antennas (e.g., the antenna 550). The wireless transceiver 2396 provides connectivity to respective networks and other electronic devices connected therewith using RF wireless signals. The wireless transceiver 2396 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:
1. A Doherty power amplifier (PA), comprising:
   a main amplifier;
   an auxiliary amplifier;
   a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
   a shunt inductor coupled to an output of the main amplifier;
   a shunt capacitor coupled to an output of the auxiliary amplifier; and
   a transformer, the transformer comprising:
      a first inductor coupled between the output of the main amplifier and the output of the auxiliary amplifier; and
      a second inductor magnetically coupled with the first inductor.
2. The Doherty PA of clause 1, wherein the phase shift is between 100 degrees and 180 degrees.
3. The Doherty PA of clause 1 or 2, wherein the second inductor is coupled between an antenna and a ground.
4. The Doherty PA of any one of clauses 1 to 3, wherein the shunt inductor is coupled between the output of the main amplifier and a voltage supply rail.
5. The Doherty PA of clause 4, wherein the shunt capacitor is coupled between the output of the auxiliary amplifier and a ground.
6. The Doherty PA of any one of clauses 1 to 3, wherein the first inductor includes a tap coupled to a voltage supply rail.
7. The Doherty PA of clause 6, further including a coupling capacitor, wherein the coupling capacitor is coupled between the shunt inductor and a ground, and the shunt inductor is coupled between the output of the main amplifier and the coupling capacitor.
8. The Doherty PA of clause 7, wherein the shunt capacitor is coupled between the output of the auxiliary amplifier and a ground.
9. The Doherty PA of any one of clauses 6 to 8, wherein the tap is located at a center of the first inductor.
10. The Doherty PA of any one of clauses 1 to 9, further comprising a first capacitor coupled in parallel with the first inductor.
11. The Doherty PA of clause 10, further comprising a second capacitor coupled in parallel with the second inductor.
12. The Doherty PA of any one of clauses 1 to 11, wherein the main amplifier, the auxiliary amplifier, and the shunt capacitor are integrated on a die.
13. The Doherty PA of any one of clauses 1 to 12, wherein the power splitting and phase shifting circuit comprises:
   a power splitter having an input coupled to an input of the Doherty PA, a first output coupled to the input of the main amplifier, and a second output; and
   a phase shifter coupled between the second output of the power splitter and the input of the auxiliary amplifier, wherein the phase shifter is configured to shift a phase of the second RF signal by the phase shift.
14. The Doherty PA of anyone of clauses 1 to 12, wherein the power splitting and phase shifting circuit comprises:
   a power splitter having an input coupled to an input of the Doherty PA, a first output, and a second output;
   a first phase shifter coupled between the first output and the input of the main amplifier; and
   a second phase shifter coupled between the second output and the input of the auxiliary amplifier, wherein each of the first phase shifter and the second phase shifter contributes to the phase shift between the first RF signal and the second RF signal.
15. The Doherty PA of any one of clauses 1 to 14, wherein the auxiliary amplifier is configured to turn on when the main amplifier is driven into saturation.
16. The Doherty PA of any one of clauses 1 to 15, wherein the first inductor comprises a first planar inductor in a first metal layer, and the second inductor comprises a second planar inductor in a second metal layer and overlapping the first planar inductor.
17. The Doherty PA of any one of clauses 1 to 15, wherein the first inductor comprises a first planar inductor, and the second inductor comprises a second planar inductor located within the first planar inductor.
18. A system for wireless communications, comprising:
   a radio frequency front-end (RFFE) module coupled to an antenna and comprising:
      a main amplifier;
      an auxiliary amplifier;
      a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
      a shunt inductor coupled to an output of the main amplifier;
      a shunt capacitor coupled to an output of the auxiliary amplifier; and
      a transformer, the transformer comprising:
         a first inductor coupled between the output of the main amplifier and the output of the auxiliary amplifier; and
         a second inductor magnetically coupled with the first inductor and coupled to the antenna.
19. The system of clause 18, wherein the phase shift is between 100 degrees and 180 degrees.
20. The system of clause 18 or 19, wherein the RFFE module comprises a die, and the main amplifier, the auxiliary amplifier, and the shunt capacitor are integrated on the die.
21. The system of clause 20, wherein the RFFE module comprises a substrate, the die is mounted on the substrate, and the transformer is on the substrate.
22. The system of any one of clauses 18 to 21, wherein the first inductor comprises a first planar inductor in a first metal layer, and the second inductor comprises a second planar inductor in a second metal layer and overlapping the first planar inductor.
23. The system of any one of clauses 18 to 21, wherein the first inductor comprises a first planar inductor, and the second inductor comprises a second planar inductor located within the first planar inductor.
24. A Doherty power amplifier (PA), comprising:
   a main amplifier;
   an auxiliary amplifier;
   a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
   a shunt inductor coupled to an output of the main amplifier;
   a shunt capacitor coupled to an output of the auxiliary amplifier; and
   a differential load coupled between the output of the main amplifier and the output of the auxiliary amplifier.
25. The Doherty PA of clause 24, wherein the phase shift is between 100 degrees and 180 degrees.
26. The Doherty PA of clause 24 or 25, wherein the shunt inductor is coupled between the output of the main amplifier and a voltage supply rail.
27. The Doherty PA of clause 26, wherein the shunt capacitor is coupled between the output of the auxiliary amplifier and a ground.
28. The Doherty PA of any one of clauses 24 to 27, wherein the power splitting and phase shifting circuit comprises:
   a power splitter having an input coupled to an input of the Doherty PA, a first output coupled to the input of the main amplifier, and a second output; and
   a phase shifter coupled between the second output of the power splitter and the input of the auxiliary amplifier, wherein the phase shifter is configured to shift a phase of the second RF signal by the phase shift.
29. The Doherty PA of any one of clauses 24 to 27, wherein the power splitting and phase shifting circuit comprises:
   a power splitter having an input coupled to an input of the Doherty PA, a first output, and a second output;
   a first phase shifter coupled between the first output and the input of the main amplifier; and
   a second phase shifter coupled between the second output and the input of the auxiliary amplifier, wherein each of the first phase shifter and the second phase shifter contributes to the phase shift between the first RF signal and the second RF signal.
30. The Doherty PA of any one of clauses 24 to 29, wherein the auxiliary amplifier is configured to turn on when the main amplifier is driven into saturation.
31. The Doherty PA of any one of clauses 24 to 30, wherein the differential load comprises a transformer, the transformer comprising:
   a first inductor coupled between the output of the main amplifier and the output of the auxiliary amplifier; and
   a second inductor magnetically coupled with the first inductor.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated that an “inductor” may include multiple inductors coupled in series. It is also to be appreciated than an “input” may be a single-ended input, a differential input, or one of two inputs of a differential input, and an “output” may be a single-ended output, a differential output, or one of two outputs of a differential output.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A Doherty power amplifier (PA), comprising:
a main amplifier;
an auxiliary amplifier;
a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
a shunt inductor coupled to an output of the main amplifier;
a shunt capacitor coupled to an output of the auxiliary amplifier; and
a transformer, the transformer comprising:
a first inductor coupled between the output of the main amplifier and the output of the auxiliary amplifier; and
a second inductor magnetically coupled with the first inductor.

2. The Doherty PA of claim 1, wherein the phase shift is between 100 degrees and 180 degrees.

3. The Doherty PA of claim 1, wherein the second inductor is coupled between an antenna and a ground.

4. The Doherty PA of claim 1, wherein the shunt inductor is coupled between the output of the main amplifier and a voltage supply rail.

5. The Doherty PA of claim 4, wherein the shunt capacitor is coupled between the output of the auxiliary amplifier and a ground.

6. The Doherty PA of claim 1, wherein the first inductor includes a tap coupled to a voltage supply rail.

7. The Doherty PA of claim 6, further including a coupling capacitor, wherein the coupling capacitor is coupled between the shunt inductor and a ground, and the shunt inductor is coupled between the output of the main amplifier and the coupling capacitor.

8. The Doherty PA of claim 7, wherein the shunt capacitor is coupled between the output of the auxiliary amplifier and a ground.

9. The Doherty PA of claim 6, wherein the tap is located at a center of the first inductor.

10. The Doherty PA of claim 1, further comprising a first capacitor coupled in parallel with the first inductor.

11. The Doherty PA of claim 10, further comprising a second capacitor coupled in parallel with the second inductor.

12. The Doherty PA of claim 1, wherein the main amplifier, the auxiliary amplifier, and the shunt capacitor are integrated on a die.

13. The Doherty PA of claim 1, wherein the power splitting and phase shifting circuit comprises:
a power splitter having an input coupled to an input of the Doherty PA, a first output coupled to the input of the main amplifier, and a second output; and
a phase shifter coupled between the second output of the power splitter and the input of the auxiliary amplifier, wherein the phase shifter is configured to shift a phase of the second RF signal by the phase shift.

14. The Doherty PA of claim 1, wherein the power splitting and phase shifting circuit comprises:
a power splitter having an input coupled to an input of the Doherty PA, a first output, and a second output;
a first phase shifter coupled between the first output and the input of the main amplifier; and
a second phase shifter coupled between the second output and the input of the auxiliary amplifier, wherein each of the first phase shifter and the second phase shifter contributes to the phase shift between the first RF signal and the second RF signal.

15. The Doherty PA of claim 1, wherein the auxiliary amplifier is configured to turn on when the main amplifier is driven into saturation.

16. A system for wireless communications, comprising:
a radio frequency front-end (RFFE) module coupled to an antenna and comprising:
a main amplifier;
an auxiliary amplifier;
a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
a shunt inductor coupled to an output of the main amplifier;
a shunt capacitor coupled to an output of the auxiliary amplifier; and
a transformer, the transformer comprising:
a first inductor coupled between the output of the main amplifier and the output of the auxiliary amplifier; and
a second inductor magnetically coupled with the first inductor and coupled to the antenna.

17. The system of claim 16 wherein the phase shift is between 100 degrees and 180 degrees.

18. The system of claim 16, wherein the RFFE module comprises a die, and the main amplifier, the auxiliary amplifier, and the shunt capacitor are integrated on the die.

19. The system of claim 18, wherein the RFFE module comprises a substrate, the die is mounted on the substrate, and the transformer is on the substrate.

20. A Doherty power amplifier (PA), comprising:
a main amplifier;
an auxiliary amplifier;
a power splitting and phase shifting circuit configured to receive an input radio frequency (RF) signal, split the input RF signal into a first RF signal and a second RF signal, output the first RF signal to an input of the main amplifier, output the second RF signal to an input of the auxiliary amplifier, and provide a phase shift between first RF signal and the second RF signal;
a shunt inductor coupled to an output of the main amplifier;
a shunt capacitor coupled to an output of the auxiliary amplifier; and
a differential load coupled between the output of the main amplifier and the output of the auxiliary amplifier.
